(19) United States
(12) Patent Application Publication
(10) Pub. No.: US 2024/0371613 A1
(43) Pub. Date: Nov. 7, 2024

(54) HIGH-THROUGHPUT PLASMA LID FOR SEMICONDUCTOR MANUFACTURING PROCESSING CHAMBERS

(71) Applicant: Applied Materials, Inc., Santa Clara, CA (US)

(72) Inventors: Muhannad Mustafa, Milpitas, CA (US); Janisht Golcha, San Francisco, CA (US); Sanjeev Baluja, Campbell, CA (US); Srinivas Gandikota, Santa Clara, CA (US); Yixiong Yang, Fremont, CA (US)

(73) Assignee: Applied Materials, Inc., Santa Clara, CA (US)

(21) Appl. No.: 18/654,221

(22) Filed: May 3, 2024

Related U.S. Application Data
(60) Provisional application No. 63/463,869, filed on May 3, 2023.

(51) Int. Cl. H01J 37/32; C23C 16/455

(52) U.S. Cl. CPC H01J 37/32807; C23C 16/45536; H01J 37/32082; H01J 37/32449; H01J 37/32513; H01J 37/32715

(57) ABSTRACT

Semiconductor manufacturing processing chambers having an RF isolator between the support ring and the showerhead and/or an RF gasket between the showerhead and the gas funnel are described. A cap insert with a cap housing around the cap insert is on the gas funnel and an RF feed is in contact with the showerhead. A substrate support can be included and may have an RF return path directed through the substrate support.

### CROSS-REFERENCE TO RELATED APPLICATIONS

This application claims priority to U.S. Provisional Application No. 63/463,869, filed May 3, 2023, the entire disclosure of which is hereby incorporated by reference herein.

### TECHNICAL FIELD

Embodiments of the disclosure generally relate to apparatus and methods for semiconductor manufacturing using plasma processing. In particular, embodiments of the disclosure relate to apparatus and methods for high-temperature plasma processing with radio frequency isolation.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

Current process chamber lids are used primarily for plasma-based chemical vapor deposition (CVD) processes. These lids are not designed for atomic layer deposition (ALD) plasma processes. ALD processes require faster saturation and fast purging capabilities.

Accordingly, there is a need in the art for apparatus and methods for plasma-enhanced atomic layer deposition with improved saturation and/or purging abilities.

### SUMMARY

In some aspects, the techniques described herein relate to a semiconductor manufacturing processing chamber including: a chamber body having a sidewall, bottom and lid enclosing an interior; a support ring on the sidewall; an RF isolator on the support ring; a showerhead on the ceramic isolator, the showerhead having a front surface and a back surface defining a thickness of the showerhead, and a plurality of apertures extending through the thickness of the showerhead; a gas funnel on the showerhead, the gas funnel having a front surface and a back surface with an opening extending through a center of the gas funnel, the front surface having a concave-shaped inner portion and an outer portion, the outer portion of the front surface of the gas funnel in contact with the back surface of the showerhead to form a gas plenum between the back surface of the showerhead and an inner portion of the front surface of the gas funnel at the concave-shaped front surface; a cap insert on the gas funnel, the cap insert having an upper portion and a lower portion, an opening in a bottom surface of the cap insert aligned with the opening in the gas funnel, the cap insert having at least one gas inlet in the upper portion; a cap housing around the cap insert, the cap housing in contact with the back surface of the gas funnel; and an RF feed in contact with the showerhead.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic view of a semiconductor manufacturing processing chamber 100 according to one or more embodiment of the disclosure.

FIG. 2 shows an expanded view of the semiconductor manufacturing processing chamber 100 of FIG. 1 at region II.

FIG. 3 shows a schematic representation of the RF power connections in a semiconductor manufacturing processing chamber 100 according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

One or more embodiments of the disclosure advantageously provide semiconductor manufacturing process chamber lids with faster saturation times. Some embodiments advantageously provide process chamber lids with increased purging capabilities. Some embodiments advantageously provide process chamber lids with high-temperature plasma capabilities.

One or more embodiments of the disclosure provide semiconductor manufacturing process chamber lids with radio frequency (RF) plasma capabilities on a high conductance showerhead lid. Some embodiments include an RF feed with an RF match through the funnel part of the gas distribution assembly.

In some embodiments, one or more isolators are incorporated to prevent RF leakage and to have a complete ground path for RF return. In some embodiments, a cap housing made from a ceramic material is used for RF isolation.

Some embodiments incorporate a showerhead with increased number of holes with larger diameters, resulting in increased conductance and increased operating temperatures. In some embodiments, the showerhead has greater than 2100 holes. In some embodiments, the showerhead holes have a diameter of about 40 mils.

Some embodiments of the disclosure incorporate a showerhead, funnel and cap insert coated with a ceramic material. In some embodiments, the ceramic material comprises aluminum oxide (Al₂O₃), also referred to as alumina. In some embodiments, the aluminum oxide showerhead, funnel and/or cap insert allow for compatibility with chlorine (Cl₂) and hydrogen radical (H*) plasma.

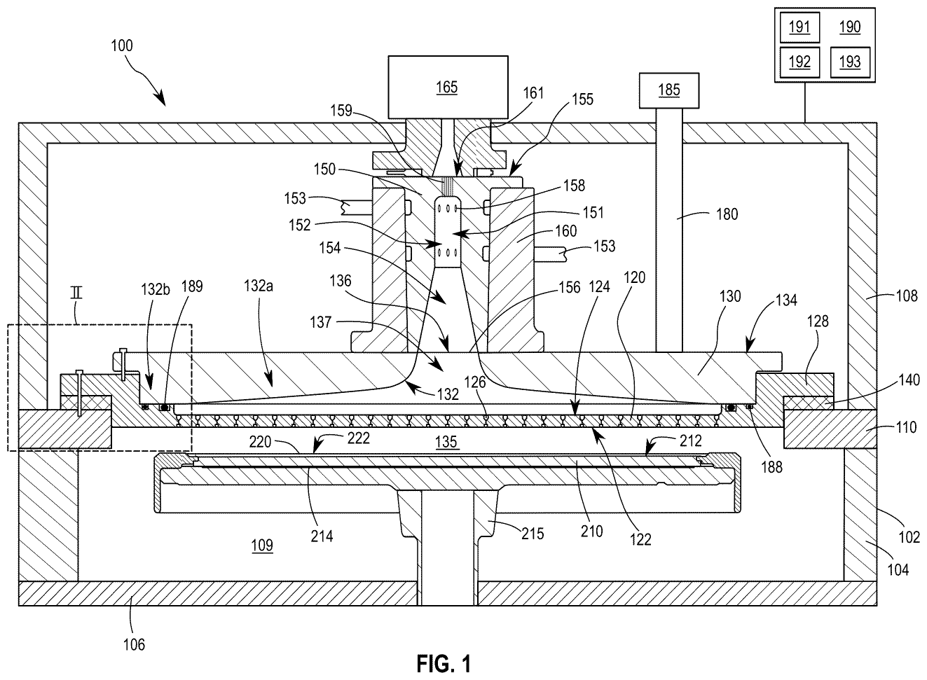

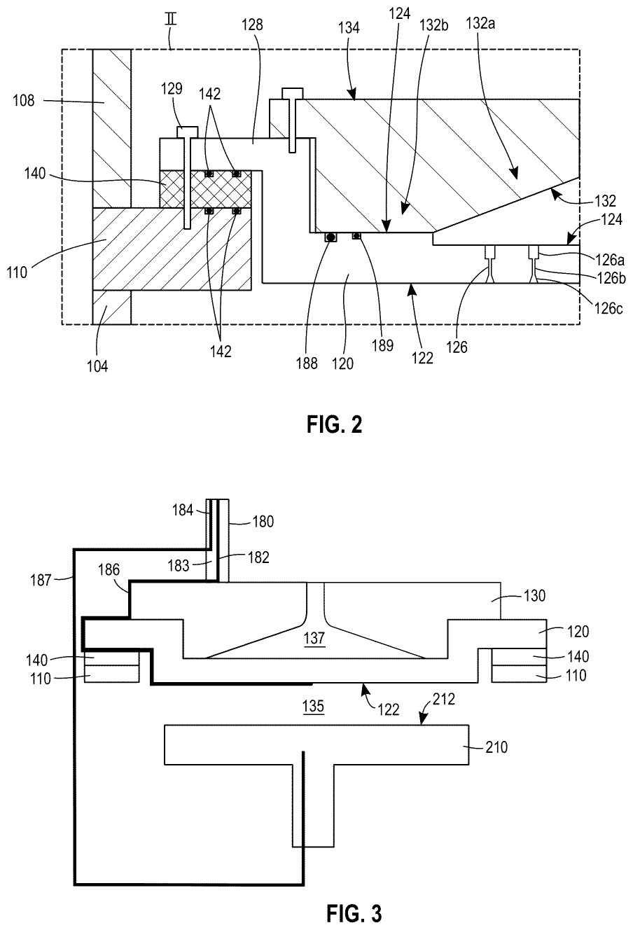

Referring to FIGS. 1 and 2, one or more embodiments of the disclosure are directed to semiconductor manufacturing processing chambers 100. FIG. 1 shows a cross-sectional schematic view of a semiconductor manufacturing processing chamber 100 according to one or more embodiment of the disclosure. FIG. 2 shows an expanded view of the semiconductor manufacturing processing chamber 100 of FIG. 1 at region II.

The semiconductor manufacturing processing chamber 100 includes a chamber body 102 with a sidewall 104, bottom 106 and chamber lid 108 that enclose an interior 109 of the chamber. The chamber body 102 can be made of any suitable material known to the skilled artisan. For example, the chamber body 102 in some embodiments is made of stainless steel. The various components of the embodiments illustrated in the Figures have different cross-hatching for visualization purposes. The different cross-hatching is only to make it easier to distinguish between parts and is not related to the materials of construction.

The semiconductor manufacturing processing chamber 100 illustrated has a support ring 110 positioned on the sidewall 104. The support ring 110 can be considered a part of the sidewall 104, or a part of the chamber lid 108 or a separate component. The support ring 110 can be made of any suitable material known to the skilled artisan. For example, in some embodiments, the support ring 110 is made of stainless steel.

A showerhead 120 is located within the interior 109 semiconductor manufacturing processing chamber 100. The showerhead 120 is part of the gas distribution assembly and may be referred to as a gas distribution plate.

The showerhead 120 has a front surface 122 and a back surface 124 that define the thickness of the showerhead 120. A plurality of apertures 126 extend through the thickness of the showerhead 120.

The thickness of the showerhead 120 is measured at the center portion of the showerhead 120 where gas can pass through the thickness through, for example, the plurality of apertures 126. FIG. 2 shows an expanded view of region II of FIG. 1. The portion of the showerhead 120 illustrated has a thinner section near the middle of the component, relative to the outer portion. The thickness T of the showerhead 120 is marked at the thinner middle portion where the plurality of apertures 126 are located. In some embodiments, the showerhead 120 has a thickness that is less than a typical semiconductor manufacturing process chamber showerhead. In some embodiments, the thickness of the showerhead 120 is less than or equal to 0.5 inches, 0.4 inches, 0.3 inches or 0.25 inches. A typical showerhead has a thickness that is greater than 1 inch. The decreased thickness according to the various embodiments of the disclosure uses less material than a typical showerhead without losing structural support.

The number of apertures 126 of some embodiments is greater than that of a typical showerhead. In some embodiments, there are at least 2000 apertures across the showerhead 120. In some embodiments, there are greater than or equal to 2000, 2100, 2200, 2300, 2400 or 2500 apertures in the showerhead 120.

Each of the plurality of apertures 126 of some embodiments, as shown in FIG. 2, have an upper portion 126a, a middle portion 126b and a lower portion 126c. The middle portion 126 is the thinnest portion of the aperture and the lower portion 126c expands to distribute the gas flow in a wider range. The upper portion 126a can be any suitable shape such as, but not limited to, a rectangular cross-section as shown in FIG. 2. The size of the apertures 126 are measured at the middle portion 126b. In some embodiments, each aperture has a minimum diameter greater than or equal to 25 mils, 30 mils, 35 mils or 40 mils. A typical showerhead has apertures with a diameter less than 15 mils. The showerhead 120 maintains structural integrity even though there are more apertures and each aperture is larger than a conventional showerhead.

The showerhead 120 can be made of any suitable material known to the skilled artisan. In some embodiments, the showerhead 120 is made of a conductive material that can be used to generate a plasma within the interior 109 of the semiconductor manufacturing processing chamber 100. In some embodiments, the showerhead 120 comprises stainless steel.

The showerhead 120 of some embodiments has an increased conductance relative to a conventional showerhead. A greater conductance allows for a more rapid exchange of gases in the interior 109 of the semiconductor manufacturing processing chamber 100. The number and size of the apertures, as well as the thickness of the showerhead 120, affect the overall conductance. In some embodiments, the showerhead 120 has a conductance greater than or equal to 50 liters/second, 55 liters/second, 60 liters/second, 65 liters/second, or 70 liters/second. For comparison purposes, a typical showerhead has a conductance less than 10 liters/second.

The thinner thickness of the showerhead, greater number and size of the apertures affect the operating temperature of the showerhead 120. In some embodiments, the showerhead 120 has an operating temperature up to and including 300° C., 275° C., 250° C., 225° C., or 200° C.

The conductance of the showerhead 120 directly impacts the amount of time it takes to exchange gases in the process chamber. The amount of time needed to fully saturate the process region 135 of the semiconductor manufacturing processing chamber 100 is referred to as the gas saturation time. A shorter gas saturation time means that the process region 135 is more quickly saturated and can be more quickly purged. The gas saturation time may also be impacted by the volume of the process region 135. In some embodiments, the semiconductor manufacturing processing chamber 100 has a gas saturation time less than or equal to 0.25 seconds, 0.2 seconds, 0.15 seconds or 0.1 second. For comparison purposes, a typical atomic layer deposition process chamber has a gas saturation time of about 1 second.

In some embodiments, the showerhead 120 has an outer flange 128 that rests on the support ring 110. One or more embodiments of the disclosure include an RF isolator 140 upon which the showerhead 120 rests. The RF isolator 140 of some embodiments, as shown in the Figures, is located on the support ring 110 and separates the showerhead 120 from directly contacting the support ring 110. The outer flange 128 of the showerhead 120 in the illustrated embodiments directly contacts the RF isolator 140. As shown in FIG. 2, the showerhead 120 is connected to the support ring 110 via the RF isolator 140 using any suitable fastener 129 known to the skilled artisan. Suitable fastener 129 include, but are not limited to, bolts. Suitable fasteners are electrically insulating by either being made of a non-conductive material or by including a non-conductive sleeve (not shown) to ensure that there is no electrical shorting between the showerhead 120 and the support ring 110.

To prevent gas leakage, one or more O-rings 142 may be positioned between the showerhead 120 and the RF isolator 140 and/or between the RF isolator 140 and the support ring 110. Suitable O-rings 142 include any material that can form a gas-tight seal between the components. Suitable O-rings 142 of some embodiments are RF isolating to further prevent electrical shorting between the showerhead 120 and the support ring 110.

The RF isolator 140 can be made of any suitable material that can electrically isolate the showerhead 120 from the support ring 110. In some embodiments, the RF isolator 140 comprises a ceramic material. In some embodiments, the ceramic comprises aluminum oxide.

The thickness of the RF isolator 140 may impact the ability to adequately electrically separate the showerhead 120 from the support ring 110. In some embodiments, the RF isolator 140 has a thickness in the range of 0.1 inch to 1 inch, or in the range of 0.15 inches to 0.75 inches, or in the range of 0.25 inches to 0.5 inches.

A gas funnel 130 is positioned on the showerhead 120. The gas funnel 130 has a front surface 132 and a back surface 134. An opening 136 extends through the center of the gas funnel 130. The front surface 132 of some embodiments has a concave-shaped inner portion 132a and an outer portion 132b. The outer portion 132b of the front surface 132 of the gas funnel 130 is in contact with the back surface 124 of the showerhead 120. A gas plenum 137 is formed between the back surface 124 of the showerhead 120 and the concave-shaped inner portion 132a of the front surface 132 of the gas funnel 130.

A cap insert 150 is located on the gas funnel 130. The cap insert 150 has an upper portion 152 and a lower portion 154. A cavity 151 extends through the length of the cap insert 150 from the top face 155 to the bottom face 157.

The shape of the cavity 151 in some embodiments, as shown in FIG. 1 varies along the length of the cavity 151. In the embodiment illustrated, the cavity 151 in the upper portion 152 of the cap insert 150 is generally cylindrical. A plurality of apertures 159 connect the top of the generally cylindrical portion of the cavity 151 with the top face 155. The upper portion 152 of the cavity 151 in some embodiments provides an inlet area for a side inject gas that forms a vortex in the cavity 151 flowing into the gas funnel 130. The length of the cavity 151 in the upper portion 152 can be any suitable length.

The cavity 151 in the lower portion 154 of the cap insert 150 has a frustoconical shape connecting the cavity 151 in the upper portion 152 with the bottom face 157. The angle and length of the frustoconical portion of the cavity 151 can be any suitable angles and/or lengths.

An opening 156 in bottom face 157 of the cap insert 150 is aligned with the opening 136 in the gas funnel 130. The opening 156 in the bottom face 157 according to some embodiments is sized to provide fluid communication between the cap insert 150 and the gas funnel 130 without introducing turbulence to the gas flowing from the cap insert 150 to the gas funnel 130.

The cap insert 150 has at least one gas inlet 158 in the upper portion 152. In the illustrated embodiment, there are three gas inlets 158 in the upper portion 152 that are configured to provide a gas flow to the cavity 151 formed through the length of the cap insert 150. In some embodiments, there are two, three, four, five, six, seven, eight, nine or ten gas inlets 158. In some embodiments, there are greater than or equal to two, three, four, five, 10, 15 or 20 gas inlets 158 in the upper portion 152 of cap insert 150 connecting a side gas inlet 153 with the cavity 151. The cap insert 150 can be made by any suitable technique and from any suitable material known to the skilled artisan.

The cap insert 150 of some embodiments has an inlet 161 in the top face 155 thereof. The inlet 161 is in fluid communication with the cavity 151 in the upper portion 152 of the cap insert 150. In the illustrated embodiment the inlet 161 in the top face 155 is in fluid communication with the cavity 151 in the upper portion 152 of the cap insert 150 through the plurality of apertures 159.

In some embodiments, as shown in FIG. 1, a remote plasma source (RPS) 165 is connected to the cap insert 150. The RPS 165 provides a flow of plasma through the inlet 161 in the top face 155 of the cap insert 150 into the cavity 151.

A cap housing 160 is positioned around the cap insert 150. The cap housing 160 is in contact with the back surface 134 of the gas funnel 130. The cap housing 160 comprises a non-conductive material to isolate the cap insert 150 from electrical interference or contact with an RF feed 180 that contacts the showerhead 120. The cap housing 160 of some embodiments comprises a ceramic. In some embodiments, the ceramic comprises aluminum oxide.

The cap housing 160 of some embodiments has at least one opening in fluid communication with side gas inlet 153 and the cavity 151 in the cap insert 150. The at least one opening (not shown) allows a gas flow from the side gas inlet 153 to pass through the cap housing 160 and into the cavity 151 of the cap insert 150. The side gas inlet 153 of some embodiments is connected to the cap housing 160 with at least one O-ring 162.

An RF (radio frequency) feed 180 is in contact with the showerhead 120. The RF feed 180 of some embodiments comprises a coaxial connection with an inner conductor 182 and an outer conductor 184 separated by an insulating layer 183, as the skilled artisan will be familiar with. The coaxial connection is shown in schematic form in FIG. 3 with the inner conductor connected to the showerhead 120. The outer conductor outer conductor 184 can be connected to any portion of the processing chamber that can be used to generate a plasma. In the illustrated embodiment, the outer conductor 184 is connected to the substrate support 210. The skilled artisan will recognize that the connections of the inner conductor 182 and the outer conductor 184 can be varied or reversed and the illustrated embodiment should not be taken as limiting the scope of the disclosure.

In some embodiments, the RF feed 180 is connected to and in electrical communication with the showerhead 120. In some embodiments, an RF gasket 188 is positioned between the gas funnel 130 and the showerhead 120. The RF gasket 188 of some embodiments is positioned outside of an O-ring 189 that forms a gas-tight seal around the gas plenum 137.

In some embodiments, the gas funnel 130 and showerhead 120 do not have direct contact outside of the RF gasket 188 to prevent RF conductivity between the gas funnel 130 and the showerhead 120.

The RF gasket 188 can be made of any suitable material and have any suitable cross-sectional shape. In some embodiments, the RF gasket 188 comprises a ceramic. In some embodiments, the ceramic comprises aluminum oxide.

Some embodiments of the semiconductor manufacturing processing chamber 100 includes a substrate support 210 within the interior 109 of the chamber body 102. The substrate support 210 has a support surface 212 spaced a distance from the showerhead 120 to create a process region 135. The substrate support 210 includes a support post 215. The substrate support 210 has a support surface 212 configured to support a semiconductor wafer 220. The support surface 212 is spaced a distance from the chamber lid 108. The top surface 222 of the semiconductor wafer 220 faces the chamber lid 108 so that the top surface 222 is exposed to process gases in the process region 135.

In some embodiments, the substrate support 210 comprises a heater 214. The heater 214 can be made of any suitable material known to the skilled artisan. In some embodiments, heater 214 comprises an electrode embedded within the substrate support 210. In some embodiments, a power supply (now shown) is connected to the electrode and power applied to the electrode causes resistive heating in the heater 214 and elevates the temperature of the substrate support 210 and semiconductor wafer 220.

In some embodiments, the substrate support 210 further comprises an electrostatic chuck (ESC) (not shown). In embodiments with an ESC, at least one power supply is connected to at least one electrode within the ESC and configured to polarize the electrodes of the ESC to generate an electrostatic charge that can chuck the semiconductor wafer 220 during processing. The skilled artisan will be familiar with the design and construction of an electrostatic chuck.

In some embodiments, as illustrated in the schematic representation of the electrical connections shown in FIG. 3, the semiconductor manufacturing processing chamber 100 comprises an RF feed 180 that is configured to have an RF feed path 186 to the showerhead 120 and an RF return path 187 from the substrate support 210. The RF feed path and RF return path can be connected to the showerhead 120 and substrate support 210 in any order. For example, in some embodiments, the RF feed path 186 connects to the substrate support 210 and the RF return path 187 connects to the showerhead 120. The RF feed path 186 and RF return path 187 are separated by the RF isolator 140.

Some embodiments of the semiconductor manufacturing processing chamber 100 further comprise at least one controller 190. The at least one control 190 of some embodiments is connected to the RF feed 180 or the RF power source 185.

In some embodiments, as shown in FIG. 1, a controller 190 is coupled to one or more of the semiconductor manufacturing processing chamber 100, the RF feed 180 through the RF power source 185, the heater 214 of the substrate support 210, side gas inlet 153 through one or more control valves, or to components thereof. For example, the system controller 190 may control the operation of the semiconductor manufacturing processing chamber 100, actuators, valves, flow controllers, power supplies, etc., and any monitoring components known to the skilled artisan that are included in the system. In operation, the system controller 190 may enable data collection and feedback from the semiconductor manufacturing processing chamber 100 to coordinate system performance.

The system controller 190 generally includes a central processing unit (CPU) 192, memory 194, and support circuits 196. The CPU 192 may be one of any form of a general-purpose processor that can be used in an industrial setting. The memory 194, or non-transitory computer-readable medium, is accessible by the CPU 192 and may be one or more of memory such as random-access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers or valves to perform processes in accordance with the various methods.

In some embodiments, the controller 190 has one or more predetermined configurations for controlling components of the semiconductor manufacturing processing chamber 100. In some embodiments, the system controller 190 has a first configuration to provide RF power across the showerhead 120 and the substrate support 210 to generate a plasma within the process region 135.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A semiconductor manufacturing processing chamber comprising:
a chamber body having a sidewall, bottom and lid enclosing an interior;
a support ring on the sidewall;
an RF isolator on the support ring;
a showerhead on the ceramic isolator, the showerhead having a front surface and a back surface defining a thickness of the showerhead, and a plurality of apertures extending through the thickness of the showerhead;
a gas funnel on the showerhead, the gas funnel having a front surface and a back surface with an opening extending through a center of the gas funnel, the front surface having a concave-shaped inner portion and an outer portion, the outer portion of the front surface of the gas funnel in contact with the back surface of the showerhead to form a gas plenum between the back surface of the showerhead and an inner portion of the front surface of the gas funnel at the concave-shaped front surface;
a cap insert on the gas funnel, the cap insert having an upper portion and a lower portion, an opening in a bottom surface of the cap insert aligned with the opening in the gas funnel, the cap insert having at least one gas inlet in the upper portion;
a cap housing around the cap insert, the cap housing in contact with the back surface of the gas funnel; and
an RF feed in contact with the showerhead.

2. The processing chamber of claim 1, further comprising an RF gasket between the gas funnel and the showerhead.

3. The processing chamber of claim 2, wherein the gas funnel and showerhead do not have direct contact outside the RF gasket to prevent RF conductivity between the gas funnel and showerhead.

4. The processing chamber of claim 2, wherein the RF gasket comprises a ceramic.

5. The processing chamber of claim 4, wherein the ceramic comprises aluminum oxide.

6. The processing chamber of claim 2, wherein the RF isolator comprises a ceramic.

7. The processing chamber of claim 6, wherein the ceramic comprises aluminum oxide.

8. The processing chamber of claim 2, wherein the cap housing comprises a ceramic.

9. The processing chamber of claim 8, wherein the ceramic comprises aluminum oxide.

10. The processing chamber of claim 2, wherein the cap insert has an inlet in a top face of the cap insert, the inlet in fluid communication with a cavity in the upper portion of the cap insert.

11. The processing chamber of claim 10, further comprising a remote plasma source connected to the cap insert to provide a flow of plasma through the inlet in the top face of the cap insert into the cavity.

12. The processing chamber of claim 10, wherein the cap insert has at least one side gas inlet in the upper portion, the at least one side gas inlet in fluid communication with the cavity.

13. The processing chamber of claim 2, further comprising a substrate support within the interior of the chamber body, the substrate support having support surface spaced a distance from showerhead to create a process region.

14. The processing chamber of claim 13, wherein the RF feed is configured to have an RF feed path to the showerhead and an RF return path from the substrate support, the RF feed path and RF return path separated by the RF isolator.

15. The processing chamber of claim 14, further comprising at least one controller connected to the RF feed.

16. The processing chamber of claim 15, wherein the at least one controller has a first configuration to provide RF power across the showerhead and substrate support to generate a plasma in the process region.

17. The processing chamber of claim 2, wherein the showerhead has at least 2000 apertures, each aperture having a minimum diameter greater than or equal to 30 mils.

18. The processing chamber of claim 17, wherein the showerhead has a conductance greater than 50 liters/second and a thickness less than 0.5 inches.

19. The processing chamber of claim 18, wherein the showerhead has an operating temperature up to and including 250° C.

20. The processing chamber of claim 18, wherein the process region has a gas saturation time less than or equal to 0.25 seconds.
